(19) United States
(12) Patent Application Publication
(10) Pub. No.: US 2025/0068207 A1
(43) Pub. Date: Feb. 27, 2025

(54) COMPACT PHOTONIC PROCESSOR ARCHITECTURE

(71) Applicant: Lightmatter, Inc., Boston, MA (US)

(72) Inventors: Nicholas C. Harris, Menlo Park, CA (US); Anthony Kopa, Somerville, MA (US); Carl Ramey, Westborough, MA (US); Darius Bunandar, Boston, MA (US); Michael Gould, La Honda, CA (US)

(73) Assignee: Lightmatter, Inc., Boston, MA (US)

(21) Appl. No.: 18/809,872

(22) Filed: Aug. 20, 2024

Related U.S. Application Data
(60) Provisional application No. 63/520,781, filed on Aug. 21, 2023.

(51) Int. Cl. G06E 3/00; H03M 1/66

(52) U.S. Cl. CPC G06E 3/008; H03M 1/66

(57) ABSTRACT

Described herein are compact, power efficient photonic processors deigned to handle general matrix-matrix (GEMM) operations. A photonic processor may comprise a controller, an optical interferometer, a plurality of signal drivers, and an optical receiver. The controller is configured to obtain a vector of input values and a matrix of parameters. The optical interferometer comprises an output and a plurality of optical phase shifters. Each signal driver of the plurality of signal drivers is configured to control a respective phase shifter to phase shift light traveling in the optical interferometer based on i) a polarity set by a respective parameter of the matrix, and ii) an amount set by a respective input value of the vector. The optical receiver is coupled to the output of the optical interferometer.

### CROSS-REFERENCE TO RELATED APPLICATIONS

This application claims the benefit under 35 U.S.C. § 119 (e) of U.S. Provisional Patent Application Ser. No. 63/520,781, entitled “PHOTONIC PROCESSOR AND RELATED METHODS,” filed on Aug. 21, 2023, under Attorney Docket No. L0858.70082US00, which is hereby incorporated herein by reference in its entirety.

### BACKGROUND

Deep learning, machine learning, latent-variable models, neural networks, and other matrix-based differentiable programs are used to solve a variety of problems, including natural language processing and object recognition in images. Solving these problems with deep neural networks typically requires long processing times to perform the required computation. The most computationally intensive operations in solving these problems are often mathematical matrix operations, such as matrix multiplication.

### SUMMARY OF THE DISCLOSURE

Some embodiments relate to a photonic processor, comprising a first optical interferometer having a plurality of segments, wherein each segment of the plurality of segments comprises a plurality of optical phase shifters having different dimensions relative to one another; a plurality of differential transmission lines, each transmission line of the plurality of differential transmission lines coupling a digital-to-analog converter (DAC) to a respective segment of the first optical interferometer; a first plurality of signal drivers, each signal driver of the first plurality of signal drivers coupling a first differential transmission line to a respective phase shifter of a first segment of the plurality of segments; and a differential optical receiver coupled to an output of the first optical interferometer.

In some embodiments, each signal driver of the first plurality of signal drivers is configured to control the respective phase shifter based on a digital input having either a first state or a second state. In the first state, the signal driver drives the respective phase shifter in accordance with a first polarity, and in the second state, the signal driver drives the respective phase shifter in accordance with a second polarity.

In some embodiments, the first optical interferometer comprises a pair of counterpart phase shifters comprising a first phase shifter on a first arm of the first optical interferometer and a second phase shifter on a second arm of the optical interferometer. In the first polarity, the first phase shifter causes a clockwise phase shift in the first arm and the second phase shifter causes a counterclockwise phase shift in the second arm, and in the second polarity, the first phase shifter causes a counterclockwise phase shift in the first arm and the second phase shifter causes a clockwise phase shift in the second arm.

In some embodiments, the photonic processor further comprises a second plurality of signal drivers, each signal driver of the second plurality of signal drivers coupling a second differential transmission line to a respective phase shifter of a second segment of the plurality of segments.

In some embodiments, the plurality of optical phase shifters of the first segment have dimensions arranged in accordance with a binary scale.

In some embodiments, the plurality of optical phase shifters of the first segment have doped well of different lengths relative to one another.

In some embodiments, the plurality of optical phase shifters of the first segment have different numbers of doped wells relative to one another.

In some embodiments, the doped wells of the first segment have same dimensions.

In some embodiments, the photonic processor further comprises a second optical interferometer having a plurality of segments, wherein each segment of a plurality of segments of the second optical interferometer comprises a plurality of optical phase shifters having different dimensions relative to one another.

In some embodiments, each transmission line of the plurality of differential transmission lines couples a DAC to a respective segment of the second optical interferometer, and each signal driver of the first plurality of signal drivers couples the first differential transmission line to a respective phase shifter of a first segment of the plurality of segments of the second optical interferometer.

Some embodiments relate to a method for performing matrix multiplication using a photonic processor, comprising: obtaining a vector of input values and a matrix of parameters;
and performing matrix multiplication between the matrix and the vector at least in part by controlling a plurality of phase shifters of an optical interferometer of the photonic processor, wherein controlling the plurality of phase shifters comprises: setting a polarity of each phase shifter of the plurality of phase shifters based on a respective parameter of the matrix; and
causing each phase shifter of the plurality of phase shifters to phase shift light traveling in the optical interferometer based on the set polarity and by an amount set by a respective input value of the vector.

In some embodiments, performing the matrix multiplication between the matrix and the vector further comprises detecting the light traveling in the optical interferometer using a differential optical receiver.

In some embodiments, the optical interferometer comprises first and second arms, wherein detecting the light traveling in the optical interferometer using the differential optical receiver comprises detecting a first optical output generated by combining light traveling in the first arm with light traveling in the second arm and a second optical output generated by combining the light traveling in the first arm with the light traveling in the second arm.

In some embodiments, the plurality of phase shifters are grouped in segments, wherein the phase shifters of a first segment of the plurality of segments have different dimensions relative to one another.

In some embodiments, causing each phase shifter of the plurality of phase shifters to phase shift light traveling in the optical interferometer comprises causing a plurality of digital-to-analog converters (DAC) to generate a plurality of differential voltages encoded with the input values of the vector.

Some embodiments relate to a photonic processor, comprising a controller configured to obtain a vector of input values and a matrix of parameters; an optical interferometer comprising a first output and a plurality of optical phase shifters; a plurality of signal drivers, each signal driver of the plurality of signal drivers being configured to control a respective phase shifter to phase shift light traveling in the optical interferometer based on: a polarity set by a respective parameter of the matrix, and an amount set by a respective input value of the vector; and an optical receiver coupled to the first output of the optical interferometer.

In some embodiments, the plurality of phase shifters are grouped in segments, wherein the phase shifters of a first segment of the plurality of segments have different dimensions relative to one another.

In some embodiments, the plurality of optical phase shifters of the first segment have dimensions arranged in accordance with a binary scale.

In some embodiments, the plurality of optical phase shifters of the first segment have different numbers of doped wells relative to one another.

In some embodiments, the optical interferometer comprises a second output, wherein the optical receiver is further coupled to the second output of the optical interferometer.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A is a representation of a matrix-vector multiplication, in accordance with some embodiments.

FIG. 1B illustrates a portion of the matrix-vector multiplication of FIG. 1A, in accordance with some embodiments.

FIG. 1C is a block diagram illustrating an example of a photonic processor, in accordance with some embodiments.

FIG. 2A is a schematic diagram illustrating an optical interferometer, in accordance with some embodiments.

FIG. 2B is a schematic diagram illustrating an optical interferometer including multiple phase shifters, in accordance with some embodiments.

FIG. 2C is a cross sectional view of the optical interferometer of FIG. 2B taken along the AA′ line, in accordance with some embodiments.

FIG. 3A is a schematic diagram illustrating an optical interferometer including signal drivers for driving the phase shifters, in accordance with some embodiments.

FIG. 3B is a table illustrating how values in matrix A can be represented using a code of digital inputs, in accordance with some embodiments.

FIG. 4A is a cross sectional view of the optical interferometer of FIG. 2B taken along the BB′ line, in accordance with some embodiments.

FIG. 4B illustrates the cross sectional view of FIG. 4A in the presence of a depletion region, in accordance with some embodiments.

FIG. 4C is another cross sectional view of an optical interferometer having an alternative phase shifter implementation, in accordance with some embodiments.

FIG. 4D is yet another cross sectional view of an optical interferometer having an alternative phase shifter implementation, in accordance with some embodiments.

### DETAILED DESCRIPTION

Described herein are compact, power efficient photonic processors designed to handle general matrix-matrix (GEMM) operations. GEMM operations are ubiquitous in software algorithms, including those for graphics processing, artificial intelligence, neural networks and deep learning. Neural networks, particularly those with fully connected layers, rely heavily on linear transformations. These transformations can be efficiently represented as matrix multiplications. For example, an input vector to be transformed using a set of weights can naturally be represented as a matrix-vector multiplication. When applied to a batch of inputs, the operation becomes a matrix-matrix multiplication.

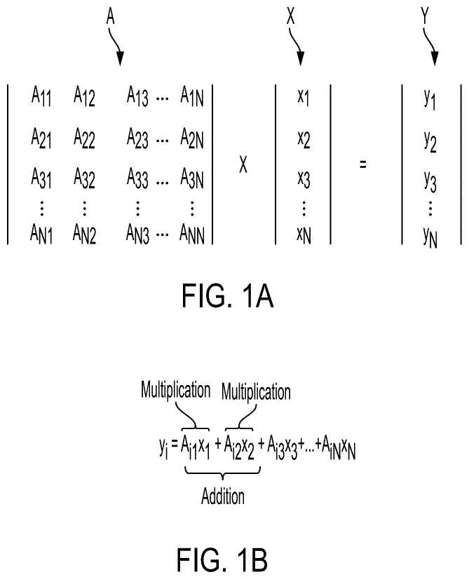

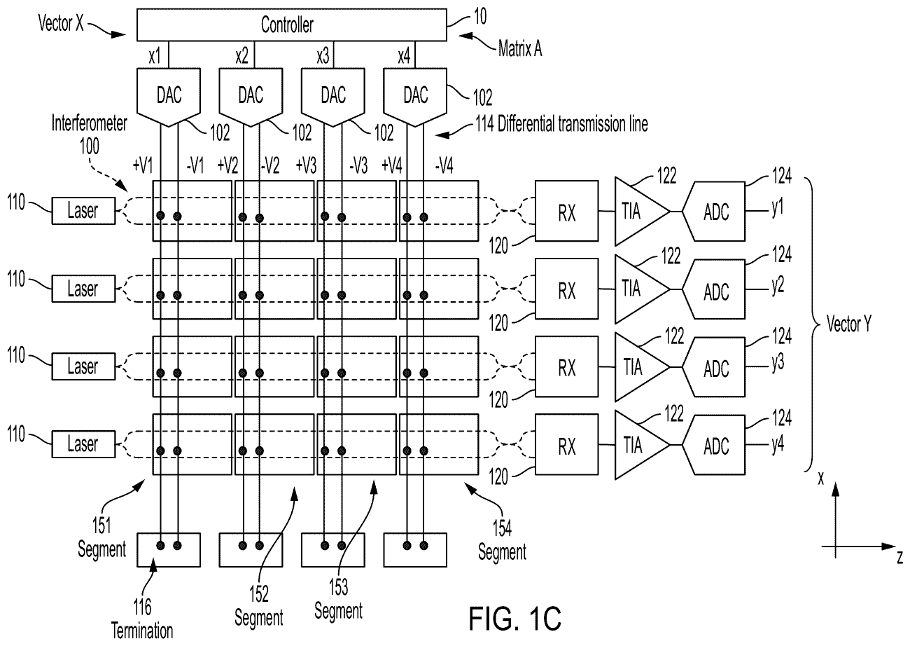

FIG. 1A is a representation of a matrix-vector multiplication, in accordance with some embodiments. Matrix A is referred to herein as “input matrix” or simply “matrix,” and the individual elements of matrix A are referred to herein as “matrix values,” “matrix parameters,” “parameters” or simply “entries.” Vector X is referred to herein as “input vector” or simply “vector,” and the individual elements of vector X are referred to as “input values,” “inputs,” “values” or simply “entries.” Vector Y is referred to herein as “output vector,” and the individual elements of vector Y are referred to as “output values,” or simply “outputs.” In this example, A is an N×N matrix, though embodiments of the present application are not limited to square matrices or to any specific dimension. Further, embodiments of the present application are not limited to two-dimensional matrices. Some embodiments apply the systems and techniques described herein to N-dimensional tensors (with N>2) by breaking down operations on these tensors into multiple 2D operations. In the context of artificial neural networks, matrix A can be a weight matrix, or a block of submatrix of a weight tensor, or an activation (batched) matrix, or a block of submatrix of the (batched) activation tensor, among several possible examples. Similarly, the input vector X can be a vector of the weight tensor or a vector of the activation tensor, for example.

The matrix-vector multiplication of FIG. 1A can be decomposed in terms of scalar multiplications and scalar additions. For example, FIG. 1B illustrates how an output value yᵢ (where i=1,2 . . . N) may be obtained as a linear combination of the input values x₁, x₂ . . . x_{N}. Obtaining yᵢ involves performing scalar multiplications (e.g., Aᵢ₁ times x₁, and Aᵢ₂ times x₂) and scalar additions (e.g., Aᵢ₁x₁ plus Aiᵢ₂x₂).

In recent years, several architectures have emerged to perform GEMM operations in the optical domain. These architectures, often referred to as photonic processors or photonic accelerators, leverage the properties of light, such as phase, amplitude, and wavelength, to perform computations. Unlike electronic accelerators, which rely on electrons moving through circuits, photonic processors use photons, which can travel at the speed of light with minimal resistance and heat generation. Photonic integrated circuits (PICs) are the backbone of photonic processors. They are similar to electronic integrated circuits but are designed to manipulate and control light. PICs contain components like waveguides, modulators, and photodetectors that guide, modulate, and detect light, respectively. In photonic processors, data (such as the entries of matrices) is encoded into the properties of light, such as its amplitude or phase. For instance, the intensity of light in a waveguide can represent a matrix entry. Matrices can be represented by arrays of light beams, with the properties of these beams corresponding to the matrix elements. In one example, matrix multiplication in photonic processors is performed by performing scalar multiplications, which in turn involves the interference of light beams. When two beams of light interfere, their amplitudes combine, which can be used to perform scalar multiplication. In another example, scalar multiplication involves modulatable detectors. Modulatable detectors are optical detectors having at least one characteristic that can be controlled using an electronic control signal. These detectors are designed so that varying the magnitude of a control signal (e.g., a voltage or a current) alters a characteristic of the detector, such as the detector's responsivity, gain, impedance, conductance, etc.

The inventors have recognized and appreciated that performing matrix multiplication in the manners noted above presents a limitation—these photonic processors use extensive amounts of real estate on the semiconductor substrate on which the processors are formed. This is because these processors perform the basic operations of matrix multiplication using mechanisms that occupy significant amounts of space. This limitation makes these conventional architectures impractical, especially for photonic processors configured to perform GEMM over matrices having hundreds or even thousands of parameters, as is often the case in deep learning. Unfortunately, the reticle size available at most semiconductor foundries is typically limited to areas between 750 mm² and 900 mm². This means that the real estate available for any given PIC is limited, thus limiting the number of photonic multipliers that can be integrated on a single PIC.

The photonic processors developed by the inventors and described herein overcome the real estate limitation described above by performing scalar multiplications using a novel mechanism. This mechanism requires significantly less space than what is required in conventional architectures, resulting in a photonic processor that can fit within the real estate constraints dictated by semiconductor foundries.

Photonic processors in accordance with some embodiments employ segmented optical interferometers, where each segment includes a set of optical phase shifters controlled by a set of signal drivers. The signal drivers associated with a segment cause light traversing the phase shifters to undergo a phase shift by an amount that is set by an entry of an input vector X and with a polarity that is set by an entry of a matrix A (the polarity indicates whether a phase shifter is to phase shift light in one direction, e.g., clockwise, or in the opposite direction, e.g., counterclockwise). Thus, the resulting phase shift is a function of both the entry of matrix A and the entry of vector B. To ensure that the resulting phase shift is not just any function of the entry of matrix A and the entry of vector B, but is a function of the product between the entry of matrix A and the entry of vector B, the inventors propose utilizing phase shifters with different modulation weights. A phase shifter with a higher modulation weight modulates the phase of incoming light to a greater extent than a phase shifter with a lower modulation weight, given the same applied voltage. Designing the phase shifters of a segment of an optical interferometer to have different modulation weights allows the processor to represent the entries of matrix A numerically. In one example, designing the phase shifters to have different modulation weights in accordance with a binary scale allows the processor to represent the entries of matrix A digitally. Representing the entries of matrix A numerically (e.g., digitally) allows the phase shifters to perform a weighted combination of the entries of vector X based on the entries of matrix that approximates the product of those entries.

The multiplication mechanism described above uses signal drivers that can be designed to be very compact. In one example, a signal driver includes an amplifier and a switch. The amplifier is configured to provide a suitable voltage to bias a phase shifter based on an entry of vector X. The switch is configured to set the polarity of a phase shifter based on an entry of matrix A. It should be noted that the act of setting the polarity of a phase shifter can be performed using different binary representations, including representations based on a “0” and a “1” or representations based on a “+1” and a “−1.” Other representations are also possible.

Accordingly, some embodiments relate to a photonic processor comprising a controller, an optical interferometer, a plurality of signal drivers, and an optical receiver. The controller is configured to obtain a vector of input values and a matrix of parameters. The optical interferometer comprises an output and a plurality of optical phase shifters. Each signal driver of the plurality of signal drivers is configured to control a respective phase shifter to phase shift light traveling in the optical interferometer based on i) a polarity set by a respective parameter of the matrix, and ii) an amount set by a respective input value of the vector. The optical receiver is coupled to the output of the optical interferometer.

Further embodiments relate to a photonic processor comprising an optical interferometer, a plurality of differential transmission lines, a plurality of signal drivers and a differential optical receiver. The optical interferometer has a plurality of segments, where each segment of the plurality of segments comprises a plurality of optical phase shifters having different dimensions relative to one another. Each transmission line of the plurality of differential transmission lines couples a digital-to-analog converter (DAC) to a respective segment of the optical interferometer. Each signal driver of the plurality of signal drivers couples a first differential transmission line to a respective phase shifter of a first segment of the plurality of segments. The differential optical receiver is coupled to an output of the first optical interferometer. In some embodiments, each signal driver is configured to control the respective phase shifter based on a digital input having either a first state or a second state. In the first state, the signal driver drives the respective phase shifter in accordance with a first polarity (e.g., clockwise); in the second state, the signal driver drives the respective phase shifter in accordance with a second polarity (e.g., counterclockwise). In some embodiments, the optical phase shifters of the first segment have dimensions arranged in accordance with a binary scale. The states of a digital input can be viewed as representing a “0” and a “1” (as in conventional bits), or using any other numeric representations, such as those including a “+1” and a “−1.”

Further embodiments relate to a method for performing matrix multiplication using a photonic processor. The method comprises obtaining a vector of input values and a matrix of parameters, and performing matrix multiplication between the matrix and the vector at least in part by controlling a plurality of phase shifters of an optical interferometer of the photonic processor. Controlling the plurality of phase shifters comprises i) setting a polarity of each phase shifter of the plurality of phase shifters based on a respective parameter of the matrix, and ii) causing each phase shifter of the plurality of phase shifters to phase shift light traveling in the optical interferometer based on the set polarity and by an amount set by a respective input value of the vector.

FIG. 1C is a block diagram illustrating an example of a photonic processor configured to perform GEMM operations. The photonic processor includes a controller 10, digital-to-analog converters (DAC) 102, differential transmission lines 114, lasers 110, optical interferometers 100, differential receivers (RX) 120, transimpedance amplifiers (TIA) 122, analog-to-digital converters (ADC) 124 and electrical terminations 116. The dimensions of the vector X and the matrix A dictate the size of the photonic processor. In some embodiments, the photonic processor may include a DAC 102 and a transmission line 114 for each value of input vector X. In some embodiments, the photonic processor may include an interferometer 100 for each output to be generated as part of output vector Y. In this example, matrix A has a dimension of 4×4, leading to a photonic processor with four optical interferometers and four DACs. However, other dimensions are possible. It should be noted that although FIG. 1C illustrates one dedicated laser 110 for each optical interferometer, not all embodiments are limited in this respect. In other embodiments, a common laser may be shared among multiple interferometers using optical power trees. It should also be noted that none of the vector X or matrix A information is encoded in the light emitted by laser(s) 110 before entering the interferometer(s) 100—the encoding is done by the phase shifters within the interferometers 100.

Controller 10 obtains digital values corresponding to the entries of vector X and the entries of matrix A. These entries may be obtained from another computer or a processor that is part of the same computer hosting the photonic processor. At the output, the photonic processor generates output vector Y, which includes four output values in this example. As discussed in detail further below, the entries of matrix A are ultimately used to set the polarities of phase shifters that are defined as part of the optical interferometers. Controller 10 provides the entries of vector X (x₁, x₂, x₃ and x₄) to DACs 102. Each DAC generates a differential voltage that is encoded with a respective entry of vector X. For example, the differential voltage represented by the pair (+V₁, −V₁) may be encoded with x₁, the differential voltage represented by the pair (+V₂, −V₂) may be encoded with x₂, the differential voltage represented by the pair (+V₃, −V₃) may be encoded with x₃ and the differential voltage represented by the pair (+V₄, −V₄) may be encoded with x₄. The differential voltages are delivered to the optical interferometers 100 using transmission lines 114 in the form of traveling waves. The ends of the transmission lines are terminated (using terminations 116) to prevent reflections.

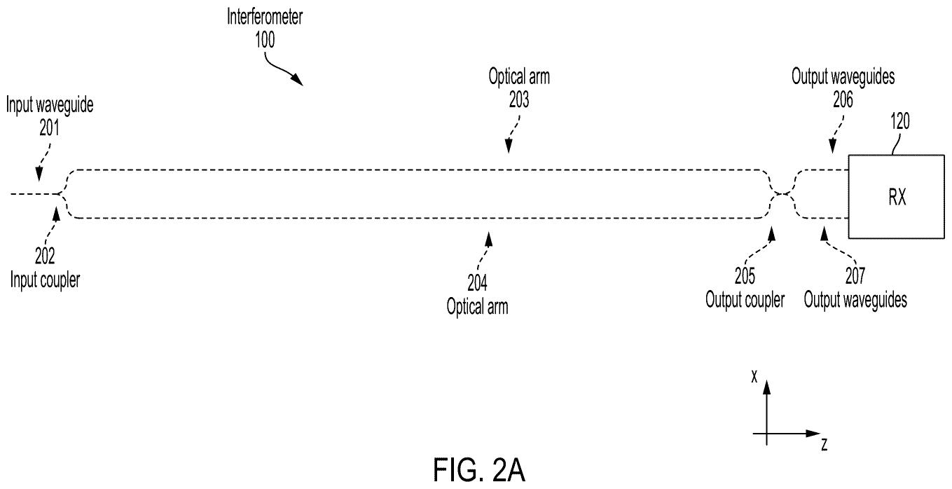

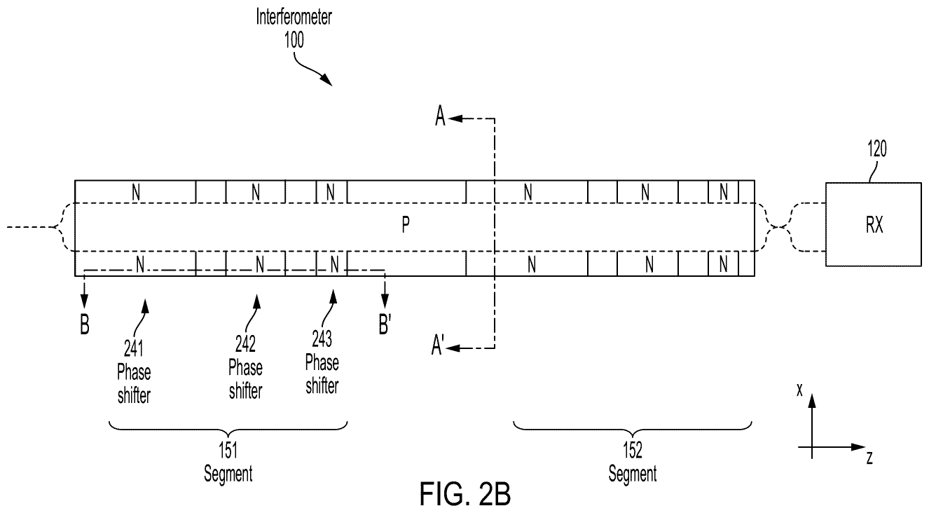

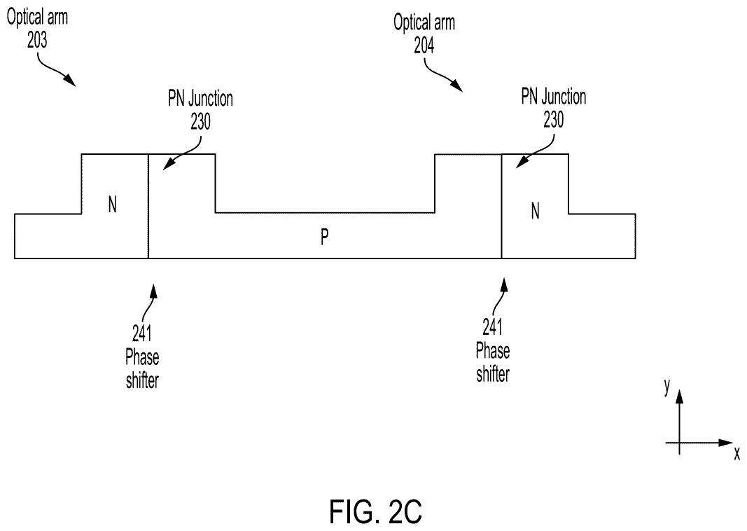

Optical interferometers 100 are described in detail below in connection with FIGS. 2A-4D. Referring first to FIG. 2A, an example of an optical interferometer that may be used as part of the photonic processor of FIG. 1C is shown. In the sole interest of illustration, FIG. 2A shows an interferometer that does not include phase shifters. However, the interferometers deployed as part of the photonic processor of FIG. 1C do include phase shifters, as discussed in detail further below. Interferometer 100 includes an input waveguide 201, optical arms 203 and 204 and output waveguides 206 and 207. An input coupler 202 couples input waveguide 201 to optical arms 203 and 204. An output coupler 205 couples optical arms 203 and 204 to output waveguides 206 and 207. Couplers 202 and 205 may be implemented using 3 dB splitters. Interferometer 100 may be viewed as operating as a Mach Zehnder interferometer (MZI), although other types of interferometers may be used in some embodiments. The amount of light transmitted out a particular output waveguide in an interferometer, such as the MZI used in some embodiments, is controlled by adjusting the phase shift in one or both of the optical arms. When two light beams traveling in optical arms 203 and 204 are recombined using coupler 205, the resulting output depends on the relative phase difference between them. If the two light beams are in phase (e.g., the phase difference is a multiple of 2π), they interfere constructively, leading to a higher intensity in output waveguide 206 and a lower intensity in output waveguide 207. If the two light beams are out of phase (e.g., the phase difference is an odd multiple of x), they interfere destructively, leading to a lower intensity in output waveguide 206 and a higher intensity in output waveguide 208. The phase difference between the two arms can be controlled by various means, such as changing the refractive index of the waveguide material (e.g., using the electro-optic effect as discussed below, or other effects such as the thermo-optic effect or the acousto-optic effect). Phase differences between the arms result in a difference between the optical path lengths associated with the arms. The light beams emerging from the two output waveguides 206 and 207 are out-of-phase, meaning that the sum of the power of the two outputs is substantially constant. By measuring the intensity of the light at the output waveguides, using RX 120, the phase difference between the two arms can be inferred, which in turn provides information about the quantity used to change the phase difference between the two arms.

FIG. 2B depicts the optical interferometer of FIG. 2A with the addition of phase shifters. In this example, the phase shifters are based on the electro-optic effect, a phenomenon whereby the refractive index of the material changes in response to an applied electric field. This effect may be achieved using a PN junction, a region defined at the interface between a p-doped semiconductor and an n-doped semiconductor. In a PN junction, a phase shift occurs as a result of injection or depletion of carriers in the depletion region, an area defined near the junction interface. Carrier injection occurs when a PN junction is forward biased (whereby the p-doped region is set to a higher potential than the n-doped region). By contrast, carrier depletion occurs when a PN junction is reverse biased (whereby the n-doped region is set to a higher potential than the p-doped region). In some embodiments, the polarity of phase shifters may be set by biasing the phase shifters at different bias points. For example, two phase shifters both operating in reverse bias may be viewed as being set to different polarities if one phase shifter is biased with a voltage that is greater (in absolute value) than the voltage biasing the other phase shifter. The inventors have recognized and appreciated that operating the phase shifters in reverse bias is beneficial over operating the phase shifters in forward bias because, even though both biases lead to phase modulation, the forward bias results in greater optical loss. Nonetheless, other ways to achieve opposite polarities are possible. For example, two phase shifters both operating in forward bias may be viewed as being set to different polarities if one phase shifter is biased with a voltage that is greater (in absolute value) than the voltage biasing the other phase shifter. As another example, two phase shifters may be viewed as being set to different polarities if one phase shifter is forward biased and the other phase shifter is reverse biased.

Interferometer 100 has phase shifters that are grouped in segments. This example illustrates two segments (151 and 152) although an interferometer may have more segments in some embodiments. For example, an interferometer may have a segment for each entry of input vector X. Thus, referring back to the photonic processor of FIG. 1C, each interferometer may have four segments (see segments 151, 152, 153 and 154). Each segment includes multiple phase shifters. For example, segment 151 includes phase shifters 241, 242 and 243. Each phase shifter may be implemented using a PN junction, an example of which is depicted in FIG. 2C, a cross sectional view of interferometer 100 obtained along to AA′ line.

The cross section of FIG. 2C illustrates optical arms 203 and 204, formed as ridge waveguides patterned on a layer of semiconductor material (e.g., silicon). The raised portions of the ridges define the waveguide cores. In this example, the region between arm 203 and 204 is p-doped, while the regions outside the arms are n-doped (although the opposite configuration is also possible). PN junctions 230 are formed at the interfaces where the p-doped region meets the n-doped regions. As a result, a pair of phase shifters 241 are formed, one for each arm of the interferometer. Although the interfaces are shown as being defined through the center of the ridge waveguides, in some embodiments the PN junction may be slightly off centered.

Referring back to FIG. 2B, the phase shifters of a segment may be designed to provide different amounts of phase shifting. Designing the phase shifters in this way results in the phase shifters have different modulation weights. A phase shifter with a higher modulation weight modulates the phase of incoming light to a greater extent than a phase shifter with a lower modulation weight, given the same applied voltage. As described in detail further below, having different modulation weights, coupled with the ability to switch the polarity of the phase shifters, allows the phase shifters to perform scalar multiplications. In some embodiments, providing the phase shifters modulation weights is accomplished by designing the phase shifters to have different dimensions relative to one another. In the example of FIG. 2B, phase shifter 241 is longer than phase shifters 242 along the axis of propagation (the z-axis), and phase shifter 242 is longer than phase shifters 243 along the axis of propagation. For example, the n-doped region of phase shifter 241 may be longer than the n-doped region of phase shifters 242 along the axis of propagation, and the n-doped region of phase shifter 242 may be longer than the n-doped region of phase shifters 243 along the axis of propagation. The region defined between the n-doped regions of adjacent phase shifters may be p-doped or may be undoped.

In some embodiments, phase shifters on opposite arms may be designed in tandem. For example, a phase shifter on an arm may be designed to have the same modulation weight as the counterpart phase shifter on the opposite arm. Two phase shifters are said to be “counterparts” when they extend in parallel to one another along the opposite arms, as shown in FIG. 2B.

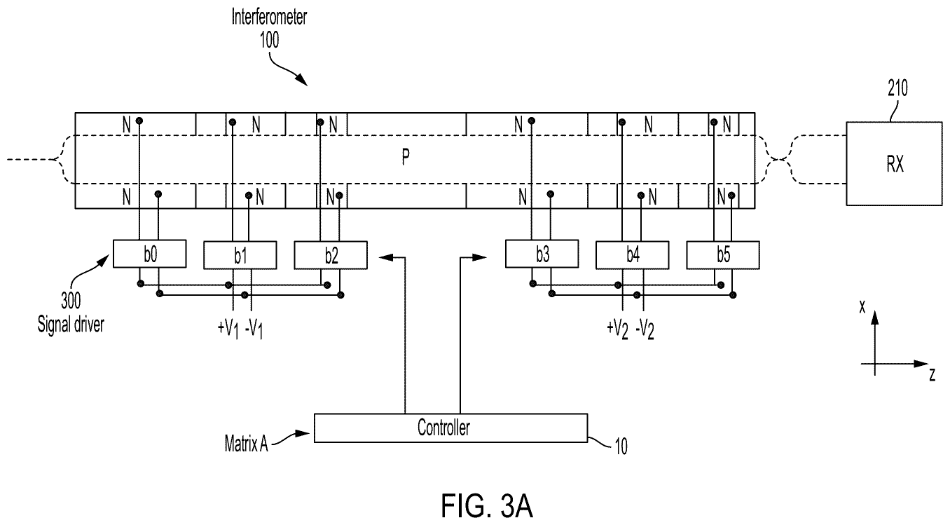

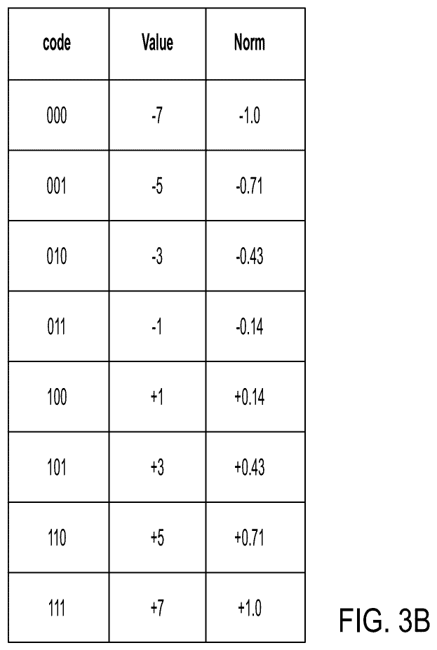

In some embodiments, the modulation weights provided by the phase shifters may be arranged in accordance with a binary scale. As such, the modulation weight of phase shifter 241 may be twice the modulation weight of phase shifter 242, and the modulation weight of phase shifter 242 may be twice the modulation weight of phase shifter 243. This may be accomplished by designing the optical phase shifters of a segment to have dimensions arranged in accordance with a binary scale. For example, the n-doped region of phase shifter 241 may be twice as long as the n-doped region of phase shifter 242, and the n-doped region of phase shifter 242 may be twice as long as the n-doped region of phase shifter 243. Designing the phase shifters to provide modulation weights in accordance with a binary scale enables analog-digital scalar multiplication, as described in connection with FIGS. 3A-3B.

FIG. 3A illustrates the interferometer of FIG. 2B with the addition of signals drivers 300 and controller 10. As described in connection with FIG. 1C, controller 10 obtains digital values corresponding to the entries of vector X and the entries of matrix A. Each signal driver 300 controls a pair of phase shifters (a phase shifter on arm 203 as well as the counterpart phase shifter on arm 204). Each signal driver 300 receives a differential voltage from the respective differential transmission line. A signal driver 300 may include circuitry designed to control the amount by which the phase shifter is to phase shift light propagating in respective arm of the interferometer. For example, a signal driver may include an amplifier configured to provide a suitable voltage to bias the phase shifter. The amount of phase shift is dictated by the input differential voltage as well as by the modulation weight associated with the phase shifter. Further, a signal driver 300 may include circuitry (e.g., a switch) to set the polarity of a pair of phase shifters based on an entry of matrix A. Controller 10 may be configured to produce digital inputs to the phase shifters depending on the entry of matrix A. The digital inputs provided by controller 10 to the phase shifters may be viewed as digital representations of the entries of matrix A. This representation is enabled by the fact that the phase shifters of a segment have different modulation weights (e.g., in accordance with a binary scale). FIG. 3B is a table illustrating how values in matrix A (see column labeled “Value”) can be represented using a code of digital inputs (see column labeled “code”). In some embodiments, the entries of matrix A may be normalized prior to being digitized, as shown in the column labeled “Norm.”

Referring back to FIG. 3A, each entry of matrix A is represented using three digital inputs. For segment 151, controller 10 controls one signal driver based on digital input b0, one signal driver based on digital input b1 and one signal driver based on digital input b2. For segment 152, controller 10 controls one signal driver based on digital input b3, one signal driver based on digital input b4 and one signal driver based on parameter digital input b5. Each digital input can have either a first value or a second value. In the first value, the signal driver controls the phase shifter of arm 203 to cause a clockwise phase shift in arm 203, and controls the phase shifter of arm 204 to cause a counterclockwise phase shift in arm 204. In the second value, the signal driver controls the phase shifter of arm 203 to cause a counterclockwise phase shift in arm 203, and controls the phase shifter of arm 204 to cause a clockwise phase shift in arm 204. As such, the value of a digital input sets the polarity of the phase shifters.

Thus, each phase shifter is controlled to produce a phase shift, where the polarity of the phase shift is set by a digital input and the amount of phase shift is set by a differential voltage. Because the values of the digital inputs depend on an entry of matrix A, and the differential voltage depends on an entry of vector X, the manner in which light is phase shifted as it travels in the optical interferometer can be viewed as being a function of the entry of matrix A and the entry of vector X. Additionally, because the phase shifters are weighted as discussed above, the manner in which light is phase shifted as it travels in the optical interferometer can be viewed as representing the product between an entry of matrix A and an entry of vector X. This is because the phase shifters perform a weighted combination of the entries of vector X based on the entries of matrix that approximates the product of those entries.

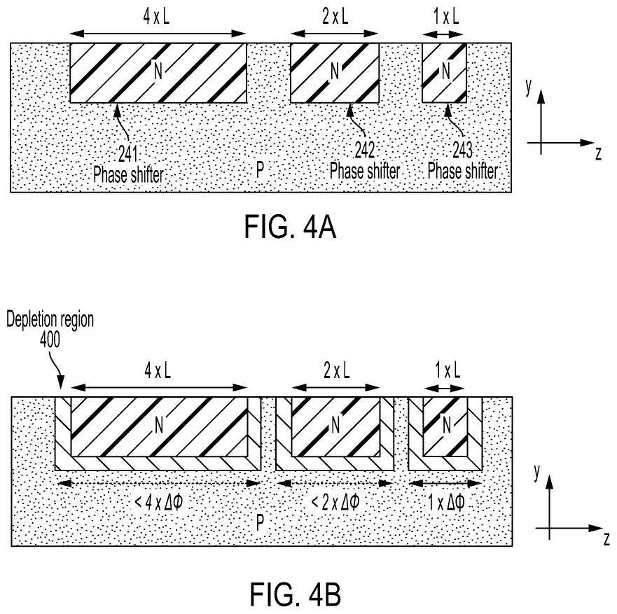

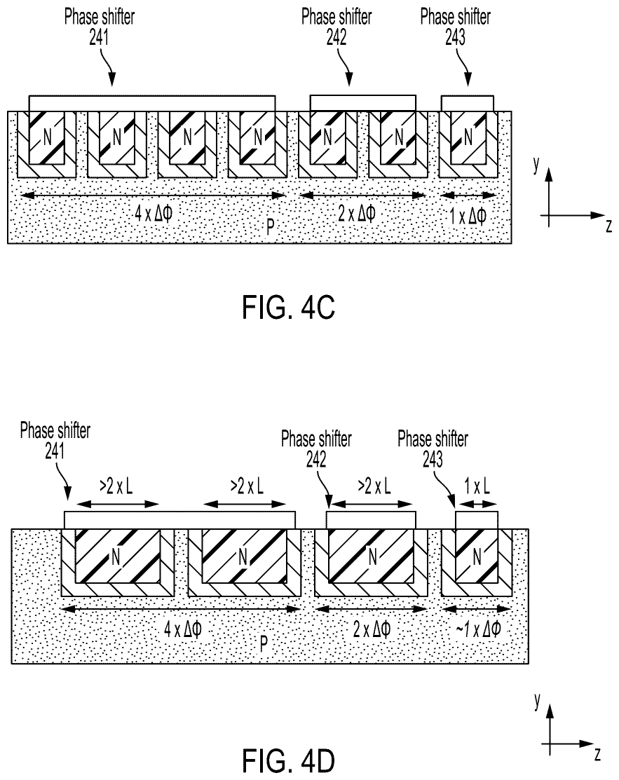

As discussed in detail above, the phase shifters of a segment may be designed to have different modulation weights. FIGS. 4A-4D illustrate different phase shifter arrangements that allow the phase shifters to have different modulation weights. FIGS. 4A-4D represent cross sectional views on an optical interferometer taken along the BB′ line of FIG. 2B. Referring first to FIG. 4A, phase shifter 243 has an n-doped region having a length along the propagation axis that is equal to L, phase shifter 242 has an n-doped region having a length along the propagation axis that is equal to 2L, and phase shifter 241 has an n-doped region having a length along the propagation axis that is equal to 4L. Unfortunately, arranging the n-doped regions in this way does not necessarily guarantee that the amount of phase shift produced by the phase shifters is perfectly binary. FIG. 4B illustrates the extent of the depletion regions 400 when a voltage is applied to the phase shifters. Given the geometry of the depletion regions (surrounding the n-wells), and the fact that the optical mode overlaps with the depletion region only in part, the total amount of phase shift is not perfectly linear with the length of the n-doped region.

Alternative arrangements may be used to ensure that the total amount of phase shift in the phase shifters is closer to being an accurate approximation of a binary scale. In the arrangement of FIG. 4C, instead of designing the n-doped regions to have different lengths, dimension diversity among the phase shifters is obtained by deploying different numbers of n-doped wells per phase shifter. In this example, phase shifter 243 includes one n-doped well, phase shifter 242 includes two n-doped wells, and phase shifter 241 includes three n-doped wells. The n-doped wells of FIG. 4C have the same length. The inventors have recognized and appreciated that designing the phase shifters as shown is FIG. 4C results in a behavior that is closer to an ideal binary scale than in FIG. 4A.

The arrangement of FIG. 4D is a hybrid between the arrangement of FIG. 4A and the arrangement of FIG. 4C. In FIG. 4D, dimension diversity between phase shifter 243 and phase shifter 242 is obtained based on n-wells having different lengths. In contrast, dimension diversity between phase shifter 242 and phase shifter 241 is obtained based on different numbers of n-wells.

Referring back to FIG. 1C, each optical interferometer further performs scalar additions among the results of the scalar multiplication performed using the phase shifters. As described above, each segment of an interferometer produces a phase shift that depends on the product of an entry of vector X times an entry of matrix A. As light traverses multiple segments, each segment phase shifts light emerging from the previous segment. The result is that light emerging at the output waveguides 206 and 207 has a phase that approximates the sum of the phase shifts produced by the segments of the interferometer. Light at the output waveguides is detected using differential optical receivers 120 by producing photocurrents. The photocurrents are converted into voltages using TIAs 122. Lastly, ADCs 124 digitize the voltages, providing outputs y₁, y₂, y₃ and y₄.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The definitions, as defined and used herein, should be understood to control over dictionary definitions, definitions in documents incorporated by reference and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some case and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately,” “substantially,” and “about” may be used to mean within +20% of a target value in some embodiments. The terms “approximately,” “substantially,” and “about” may include the target value.

Use of ordinal terms such as “first,” “second,” “third,” etc., in the claims to modify a claim element does not by itself connotate any priority, precedence, or order of one claim element over another or the temporal order in which acts of a method are performed, but are used merely as labels to distinguish one claim element having a certain name from another claim element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

What is claimed is:

1. A photonic processor, comprising:
a first optical interferometer having a plurality of segments, wherein each segment of the plurality of segments comprises a plurality of optical phase shifters having different dimensions relative to one another;
a plurality of differential transmission lines, each transmission line of the plurality of differential transmission lines coupling a digital-to-analog converter (DAC) to a respective segment of the first optical interferometer;
a first plurality of signal drivers, each signal driver of the first plurality of signal drivers coupling a first differential transmission line to a respective phase shifter of a first segment of the plurality of segments; and
a differential optical receiver coupled to an output of the first optical interferometer.

2. The photonic processor of claim 1, wherein each signal driver of the first plurality of signal drivers is configured to control the respective phase shifter based on a digital input having either a first state or a second state, wherein:
in the first state, the signal driver drives the respective phase shifter in accordance with a first polarity, and
in the second state, the signal driver drives the respective phase shifter in accordance with a second polarity.

3. The photonic processor of claim 2, wherein the first optical interferometer comprises a pair of counterpart phase shifters comprising a first phase shifter on a first arm of the first optical interferometer and a second phase shifter on a second arm of the optical interferometer, wherein:
in the first polarity, the first phase shifter causes a clockwise phase shift in the first arm and the second phase shifter causes a counterclockwise phase shift in the second arm, and
in the second polarity, the first phase shifter causes a counterclockwise phase shift in the first arm and the second phase shifter causes a clockwise phase shift in the second arm.

4. The photonic processor of claim 1, further comprising a second plurality of signal drivers, each signal driver of the second plurality of signal drivers coupling a second differential transmission line to a respective phase shifter of a second segment of the plurality of segments.

5. The photonic processor of claim 1, wherein the plurality of optical phase shifters of the first segment have dimensions arranged in accordance with a binary scale.

6. The photonic processor of claim 1, wherein the plurality of optical phase shifters of the first segment have doped well of different lengths relative to one another.

7. The photonic processor of claim 1, wherein the plurality of optical phase shifters of the first segment have different numbers of doped wells relative to one another.

8. The photonic processor of claim 7, wherein the doped wells of the first segment have same dimensions.

9. The photonic processor of claim 1, further comprising:
a second optical interferometer having a plurality of segments, wherein each segment of a plurality of segments of the second optical interferometer comprises a plurality of optical phase shifters having different dimensions relative to one another.

10. The photonic processor of claim 9, wherein:
each transmission line of the plurality of differential transmission lines couples a DAC to a respective segment of the second optical interferometer, and
each signal driver of the first plurality of signal drivers couples the first differential transmission line to a respective phase shifter of a first segment of the plurality of segments of the second optical interferometer.

11. A method for performing matrix multiplication using a photonic processor, comprising:
obtaining a vector of input values and a matrix of parameters; and
performing matrix multiplication between the matrix and the vector at least in part by controlling a plurality of phase shifters of an optical interferometer of the photonic processor, wherein controlling the plurality of phase shifters comprises:
setting a polarity of each phase shifter of the plurality of phase shifters based on a respective parameter of the matrix; and
causing each phase shifter of the plurality of phase shifters to phase shift light traveling in the optical interferometer based on the set polarity and by an amount set by a respective input value of the vector.

12. The method of claim 11, wherein performing the matrix multiplication between the matrix and the vector further comprises detecting the light traveling in the optical interferometer using a differential optical receiver.

13. The method of claim 12, wherein the optical interferometer comprises first and second arms, wherein detecting the light traveling in the optical interferometer using the differential optical receiver comprises detecting a first optical output generated by combining light traveling in the first arm with light traveling in the second arm and a second optical output generated by combining the light traveling in the first arm with the light traveling in the second arm.

14. The method of claim 11, wherein the plurality of phase shifters are grouped in segments, wherein the phase shifters of a first segment of the plurality of segments have different dimensions relative to one another.

15. The method of claim 11, wherein causing each phase shifter of the plurality of phase shifters to phase shift light traveling in the optical interferometer comprises causing a plurality of digital-to-analog converters (DAC) to generate a plurality of differential voltages encoded with the input values of the vector.

16. A photonic processor, comprising:
a controller configured to obtain a vector of input values and a matrix of parameters;
an optical interferometer comprising a first output and a plurality of optical phase shifters;
a plurality of signal drivers, each signal driver of the plurality of signal drivers being configured to control a respective phase shifter to phase shift light traveling in the optical interferometer based on:
a polarity set by a respective parameter of the matrix, and
an amount set by a respective input value of the vector; and
an optical receiver coupled to the first output of the optical interferometer.

17. The photonic processor of claim 16, wherein the plurality of phase shifters are grouped in segments, wherein the phase shifters of a first segment of the plurality of segments have different dimensions relative to one another.

18. The photonic processor of claim 17, wherein the plurality of optical phase shifters of the first segment have dimensions arranged in accordance with a binary scale.

19. The photonic processor of claim 18, wherein the plurality of optical phase shifters of the first segment have different numbers of doped wells relative to one another.

20. The photonic processor of claim 16, wherein the optical interferometer comprises a second output, wherein the optical receiver is further coupled to the second output of the optical interferometer.
